(19) United States
(12) Patent Application Publication
(10) Pub. No.: US 2022/0151112 A1
(43) Pub. Date: May 12, 2022

(54) COOLING MODULE AND COOLING MODULE RACK

(71) Applicant: ICEOTOPE GROUP LIMITED, South Yorkshire (GB)

(72) Inventors: Neil Edmunds, South Yorkshire (GB); Nathan Longhurst, South Yorkshire (GB)

(21) Appl. No.: 17/436,116

(22) PCT Filed: Mar. 4, 2020
(86) PCT No.: PCT/GB2020/050511

§ 371 Date: Sep. 3, 2021

(30) Foreign Application Priority Data
Mar. 5, 2019 (GB) 1902949.5
Mar. 5, 2019 (GB) 1902950.3

(51) Int. Cl. H05K 7/20

(52) U.S. Cl. CPC H05K 7/20772; H05K 7/20263; H05K 7/2039

(57) ABSTRACT

A cooling module and/or a computing system comprising cooling modules are provided. The computing system may comprise: a server rack for holding computing units at different heights; at least two cooling modules for mounting in the server rack, comprising a first housing enclosing a first computing unit. The two cooling modules may house different types of information technology equipment, but have the same height. The cooling module may containing an electronic device and liquid coolant. It may have one or more of: a sidewall with a reinforcement adaptation; an lower and/or upper wall with a central portion that is close to the opposite wall an internal surface further from its outer surface than in another portion of the internal volume; a separable lid with an overlapping ridge; and a thermally conductive component passing through a sidewall.

### TECHNICAL FIELD OF THE INVENTION

The disclosure concerns a cooling module, for containing a heat-generating electronic device within an internal volume and/or a computing system comprising a plurality of cooling modules mounted in a server rack.

### BACKGROUND TO THE INVENTION

Many types of electrical component generate heat during operation. In particular, electrical computer components such as motherboards, central processing units (CPUs), graphical processing units (CPUs), memory modules, hard disks and power supply units (PSUs) may dissipate substantial amounts of heat when in use. Heating of the electrical components to high temperatures can cause damage, affect performance or cause a safety hazard. Accordingly, substantial efforts have been undertaken to find efficient, high performance systems for cooling electrical components effectively and safely.

One type of cooling system uses liquid cooling. Although different liquid cooling assemblies have been demonstrated, in general the electrical components are immersed in a coolant liquid so as to provide a large surface area for heat exchange between the heat generating electrical components and the coolant.

International patent publication number WO-2010/130993 and US patent publication number 2010/0290190 (commonly assigned with this invention and the contents of which are incorporated by reference) describe a cooling device that uses a sealable module for containing one or more heat generating electronic components, together with a (primary) liquid coolant in which the electronic components are immersed. Immersion of the electronic components in a coolant that carries heat away from the electronic components can be thermodynamically-efficient. Heat is transferred from the primary liquid coolant inside the sealable module to a secondary liquid coolant, external the sealable module. This uses a conduction surface (a cold plate) with projections to reduce the distance between the conduction surface and the device being cooled. In this design, the primary liquid coolant flows by convection and expansion of the coolant can lead to pressure increases, so a significant quantity of coolant is required. A housing for the sealable module is typically made of a metal material, although the use of a synthetic plastic material is discussed as an alternative possibility. Multiple modules may be mounted in a rack.

International patent publication number WO-2018/096362 discloses a later variation on this design, in which the primary liquid coolant is pumped within the sealable module (enclosure), with a heat exchanger being provided within the enclosure for transfer of heat from the primary liquid coolant to the secondary liquid coolant. The quantity of coolant required in this later variation is significantly less than the earlier design. To avoid significant expansion due to pressure increase, the volume within the enclosure not occupied by primary liquid coolant or hardware (in other words, occupied by air) is kept to be a minimum.

These existing designs can provide high cooling efficiency. However, each cooling module is typically designed for cooling one type of electronic component or device. It is desirable to provide a cooling module and a rack for mounting multiple cooling modules in which different types of electronic component or device can be used efficiently and in a more straightforward way.

### SUMMARY OF THE INVENTION

Against this background, there is provided a computing system in line with claim 1 or claim 41 and a cooling module, for containing a heat-generating electronic device within an internal volume, in accordance with claim 18.

According to an aspect, there is generally provided a computing system, comprising: a server rack for holding a plurality of computing units at different levels in a height dimension; first and second cooling modules for mounting in the server rack, each comprising a respective housing enclosing a respective computing unit and having the same size in the height dimension. The two computing units are of different types of Information Technology Equipment (ITE). Types of ITE may include: at least one computer processing unit (CPU); at least one graphical processing unit (GPU); at least one power supply unit (PSU); one or more networking switches; and one or more disk drives. Optionally, all the dimensions of the two cooling modules are the same.

In some embodiments, all of the cooling modules in the server rack may have the same sizes in the height dimension, even though they house at least two different types of ITE in at least two different cooling modules. Alternatively, all of the cooling modules in the server rack may have one of two different sizes in the height dimension, when housing at least two different types of ITE (in at least two different cooling modules) and more preferably at least three different types of ITE (in at least three different cooling modules).

Each of the computing units is optionally made up of multiple devices of the same type of information technology equipment. One of the computing units may comprise one or more power supply units (PSUs), with the other comprising something else (for instance, a CPU or GPU). A third cooling module on the other side of the first cooling module from the second cooling module (and optionally having at least the same height and/or the same other dimensions as the first and second cooling modules) may be provided. Advantageously, two cooling modules each having one or more PSUs may be provided, but not adjacently in the server rack. However, two cooling modules each having a CPU or GPU may be provided adjacently.

Where one or more PSUs are provided in a cooling module, it may be one or more of: sufficient to supply the electrical requirements of at least 2, 3, 4, 5, 6 or all other cooling modules (for example, at least 25 kW of power); each PSU is sufficient to supply the electrical requirements of a single, other cooling module; and comprises multiples PSUs, sufficient to provide redundancy (N+1). Each computing unit may be rated to consume up to 4 kW of electrical power.

The number of cooling modules in the server rack may be at least 4, 6 or 8 and optionally higher. All of the cooling modules preferably have the same height or more preferably, all of the same dimensions.

Each cooling module may house a respective cooling liquid sealed with the respective computing unit in a respective internal volume. Each cooling module may further comprises a respective heat exchanger (which may be within the respective internal volume), configured to receive the respective cooling liquid from the respective internal volume and transfer heat from the respective liquid coolant to a respective heat sink coolant. The heat sink coolants may all be the same secondary coolant liquid (for example, water), which is provided to the cooling modules through piping in the server rack. A respective pump within each cooling module may promote the flow of the respective cooling liquid within the internal volume (to and from the heat exchanger).

In a yet further aspect, which may be combined with any other aspect as herein disclosed, there may be considered a cooling module, for containing a heat-generating electronic device within an internal volume together with a liquid coolant and typically in the form of a computer server (blade). The cooling module has a housing defining an upper wall, a lower wall opposite the upper wall and at least one sidewall connecting the lower wall and upper wall (and preferably four sidewalls to define a generally cuboid shape). The upper wall, lower wall and at least one sidewall defining the internal volume. The cooling module has one or more of a number of adaptations to improve the housing. Part, most, or substantially all of the housing may be made from plastic and/or metal (for example, cast metal or sheet metal, including steel and/or aluminium).

The adaptations may comprise one or more of: (a) the sidewall is formed from a layer of material (for instance, plastic) and some type of reinforcement adaptation that improves the resilience to pressure from the internal volume and/or its thermal insulation ability; (b) a slope or step change in the lower wall and/or the upper wall, such that the centre portions of opposite walls are closer than a periphery or such that the thickness of the upper or lower wall structure is smaller in a periphery than in the centre portion or greater in one part of the periphery than another part of the periphery; (c) the housing separates into a base and a lid that can be put together to define the internal volume, with the lid having an overhang (a ridge) that sits within the base internal volume; (d) a thermally conductive component (such as a plate, typically metal) which conducts heat from outside the internal volume to (the liquid coolant) within.

The reinforcement adaptation may be one or more of: (i) a second layer of material, spaced from the first layer so as to form a double-walled housing; (ii) a support structure attached to or formed integrally with the layer for reinforcement (such as ribs, pins, fins or ridges); and (iii) a panel attached to the first layer of material. The support structure may be formed to have a pattern comprising one or more of: elongated ribs; a criss-cross; and a tessellated shape. The panel may have a reflective inner surface.

Some or all of the periphery of the internal volume may be defined by a gutter formed along at least one edge adjacent the at least one sidewall. The gutter may be spaced further apart from the opposite wall than the central portion.

A projection from the lid may fit with a sealing part on the base (which in one example may be deformable or compressible or in another example may be formed by a recess) to create a seal. The overhang or ridge on the lid is preferable longer than the projection (or at least extends further out from the main part of the lid).

A heat exchanger (which may be within the internal volume) transfers heat from the liquid coolant to a heat sink coolant. The heat sink coolant may be a secondary liquid coolant, which may be received from external the cooling module. A pump may cause the flow of the liquid coolant within the internal volume. The pump may be located in the outer portion or elongated end, where the height dimension of the internal volume is larger.

The electronic device may comprise a planar circuit board, which may be mounted horizontally (parallel to the lower and/or upper wall) or vertically (parallel to the sidewall). The electronic device may be one or more of: a computer processing unit; a graphical processing unit; a network switch; a computer storage device; one or more disk drives; and a power supply unit. The quantity of liquid coolant is preferably insufficient to cover the heat-generating electronic device.

In another aspect, there may be considered a computing system, comprising: a server rack for holding a plurality of computing units; and two cooling modules for mounting in the server rack having the same height. Optionally, all of the dimensions of the cooling modules are the same. Each cooling module, comprises a respective electronic device as a computing unit. The two computing units are preferably different types of information technology equipment.

### BRIEF DESCRIPTION OF THE DRAWINGS

The invention may be put into practice in a number of ways and preferred embodiments will now be described by way of example only and with reference to the accompanying drawings, in which:

FIG. 1 shows a front perspective view of an embodiment of a cooling module housing in accordance with the disclosure;

FIG. 2 shows a rear perspective view of the embodiment of FIG. 1;

FIG. 3 depicts an exploded rear perspective view of the embodiment of FIG. 1 in accordance with a first design;

FIG. 4 depicts a front perspective view of the embodiment of FIG. 1 in accordance with a second design;

FIG. 5 depicts a front perspective view of the embodiment of FIG. 1 in accordance with a third design;

FIG. 6 illustrates a cross-sectional view of the embodiment of FIG. 1;

FIG. 7 illustrates a portion of FIG. 6 in more detail;

FIG. 8 shows a front perspective view of the embodiment of FIG. 1 with a lid part separated from a base portion;

FIG. 9 shows a front perspective view of a second embodiment of a cooling module housing in accordance with the disclosure;

FIG. 10 shows a rear perspective view of the embodiment of FIG. 9;

FIG. 11 depicts an exploded rear perspective view of the embodiment of FIG. 9;

FIG. 12 illustrates a schematic cross-sectional view in accordance with another embodiment of the disclosure;

FIG. 13 depicts a front face view of a server rack populated with cooling modules, in accordance with an embodiment of the disclosure; and

FIG. 14 depicts a front perspective view of the embodiment of FIG. 13.

Where the same features are shown in different drawings, identical reference numerals are employed.

### DETAILED DESCRIPTION OF PREFERRED EMBODIMENTS

The present disclosure relates to improvements in a cooling module (that is, a module for housing and cooling an electronic component or device) and a rack for mounting a plurality of cooling modules. Although both aspects are connected and in practice, may be used together, they will be described individually below. It should be appreciated that features from one aspect may be used in another aspect.

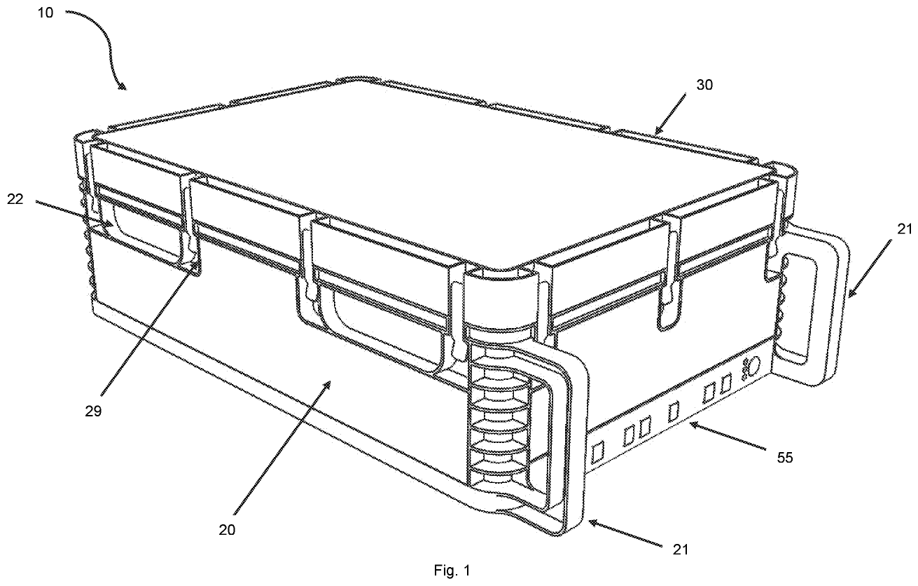

Referring first to FIG. 1, there is shown a front perspective view of an embodiment of a cooling module housing. The cooling module housing 10 comprises: a base portion 20; and a lid 30. The base portion 20 is generally cuboid shaped and defines an internal volume (shown in later drawings), which can house an electronic device for cooling and a liquid coolant. The liquid coolant will, from now on, be referred to as a primary liquid coolant. This is to distinguish it from other coolants used by the cooling module, as will be discussed below. The electronic device may be an item of Information Technology Equipment (ITE), examples of which will be discussed below.

As shown in FIG. 1, the base portion 20 comprises: rack removal handles 21; carry handles 22; clips 29; and communication and user interface panel 55. The base portion 20 is typically made from a plastic material and may be moulded. Such a plastic material is advantageously thermally insulating, so that the base portion does not become too hot to touch during operation of the electronic component or device within cooling module 10. The lid 30 is sized and shaped to fit with the base portion 20, such that when the clips 29 fit over corresponding mating portions of the lid 30, a seal is made to enclose the internal volume.

The communication and user interface panel 55 comprises at least one and typically a plurality of communication connectors for interfacing the electronic device housed within the cooling module 10 (as will be discussed below), for example Universal Serial Bus (USB) type connectors (sockets). Moreover, the panel 55 includes any visual indicators and/or buttons (such as a power button) for the electronic device housed inside the cooling module 10 to interface with the user.

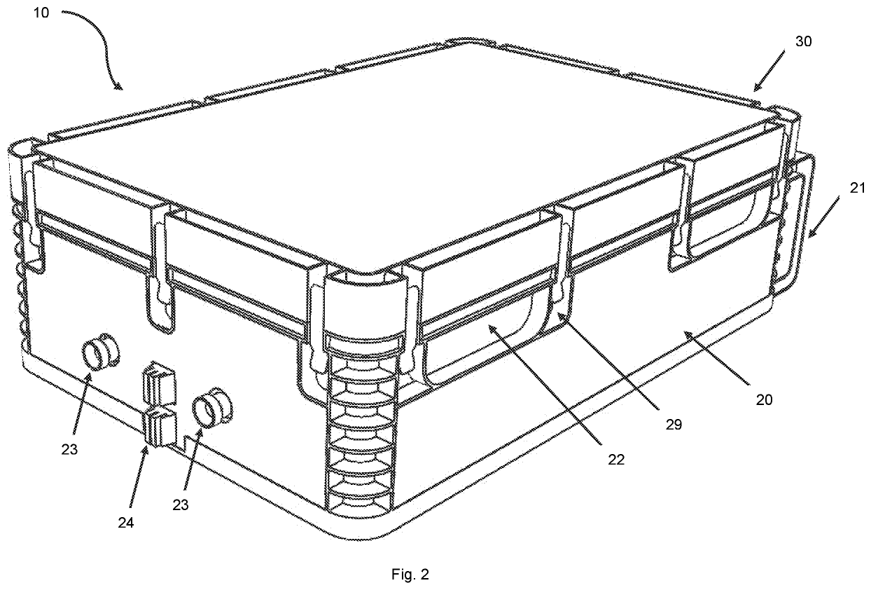

Referring next to FIG. 2, there is shown a rear perspective view of the embodiment of FIG. 1. Where the same features are shown as in a previous drawing, identical reference numerals are employed. In this drawing, additional features of the base portion 20 can be seen. Specifically, the base portion comprises: fluid connectors 23; and power connectors 24. The fluid connectors 23 are designed to receive a secondary cooling fluid, generally in the form of a secondary coolant liquid (for example, water), external the cooling module 10 and provide it to a heat exchanger (not shown) within the cooling module 10. The heat exchanger transfers heat from the primary liquid coolant within the internal volume to the secondary coolant liquid. The secondary coolant liquid therefore receives heat from the heat exchanger and then leaves the cooling module 10 via the respective fluid connector 23. The fluid connectors 23 may be configured to blind-mate with suitable connectors in a rack, for providing the secondary coolant liquid and taking it away accordingly, when the cooling module 10 is positioned in the rack.

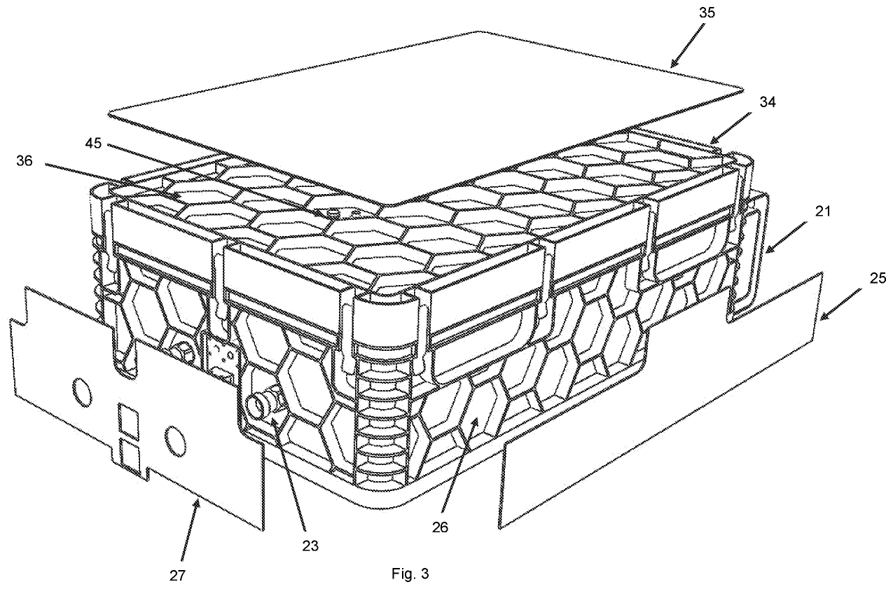

The base portion 20 and/or lid 30 is designed to provide both strength (particularly in terms of resilience to pressure from the internal volume) and insulation. Pressure from the internal volume can result from the electronic device heating the primary liquid coolant and thereby causing expansion of the primary liquid coolant and/or air also housed in the internal volume. In particular, it is intended for the level of primary liquid coolant in the internal volume to be relatively low, particularly such that the electronic device housed in the internal volume is not submerged. In general, this may result in primary liquid coolant occupying no more than 20%, 15%, 10% or even 5% of the internal volume that is not taken up by the electronic device. As a consequence, a significant quantity of air will be present in the internal volume during operation and the coefficient of thermal expansion for air is typically high in comparison with that of the primary liquid coolant. This will cause high pressure within the internal volume. Although the base portion 20 is made from a plastic material, this does not necessarily mean that the thermal insulation of the base portion 20 will be high. Since the temperature of the primary liquid coolant (and any air) within the internal volume will increase significantly during operation, thermal insulation of the housing is desirable. The same considerations in terms of strength and insulative qualities apply to the lid 30. A number of reinforcement adaptations that improve a resilience and/or thermal insulative quality of the housing, both in the base portion 20 and the lid 30 will be discussed below with reference at least to FIGS. 3 to 5.

With reference to FIG. 3, there is depicted an exploded rear perspective view of the embodiment of FIG. 1 in accordance with a first design. Where the same features are shown as in a previous drawing, identical reference numerals have been used. In this first design, the base portion 20 and lid 30 are formed using a double-wall structure. Specifically, an inner layer of plastic 26 is formed with a support structure attached to the first layer of plastic 26 or formed integrally with the first layer of plastic 26, the support structure being formed perpendicular to the first layer of plastic. In this case, the support structure takes the form of ribs arranged a tessellated hexagonal (honeycomb) shape. The support structure is coupled to the lower wall of the base portion 20. The support structure may allow the first layer of plastic 26 to be thinner than would otherwise be necessary. A second layer of plastic 25 fits over the support structure and the first layer of plastic 26 (parallel thereto), to create a double-wall. On the rear wall of the cooling module 10, a similar structure is provided using another second layer of plastic 27. This other second layer of plastic 27 is made from the same material (and typically with the same thickness) as the second layer of plastic 25, but has holes through which the fluid connectors 23 and air connectors 24 can fit.

The lid 30 is formed with a similar structure to that of the base portion 20, particularly with reference to the part of the lid 30 forming an upper wall of the cooling module 10. A first layer of plastic 36 is formed with a support structure attached to it or formed integrally with it. Again, a tessellated hexagonal (honeycomb) support structure is used. A second layer of plastic 35 fits over the first layer of plastic 36.

The sides of the lid 30 are formed slightly differently from the part forming the upper wall, without the use of the support structure. A double layer of plastic 34 is provided. Gaps between the double layers of plastic 34 allow the clips 29 to fit with the lid 30. This is shown in more detail below.

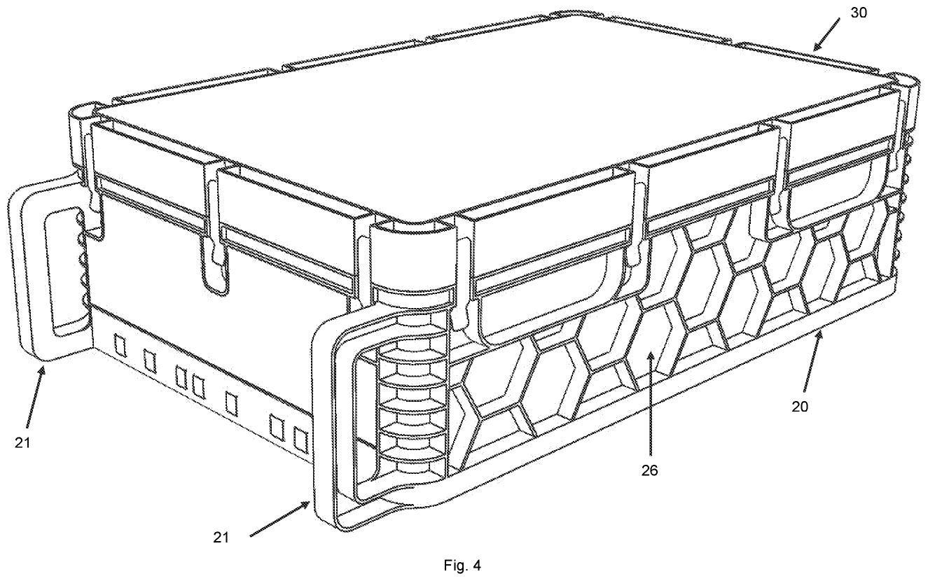

Alternatives to the first design shown in FIG. 3 are possible. Referring next to FIG. 4, there is depicted a front perspective view of the embodiment of FIG. 1 in accordance with a second design. This uses a single wall structure. Where the same features as shown in a previous drawing are depicted, identical reference numerals have been employed. This second design is similar to the first design (shown in FIG. 3), but does not use a second layer of plastic (parallel to the first layer of plastic), at least in the base portion 20. However, a support structure is still provided on the first layer of plastic 26, to improve strength (pressure resilience) and insulation.

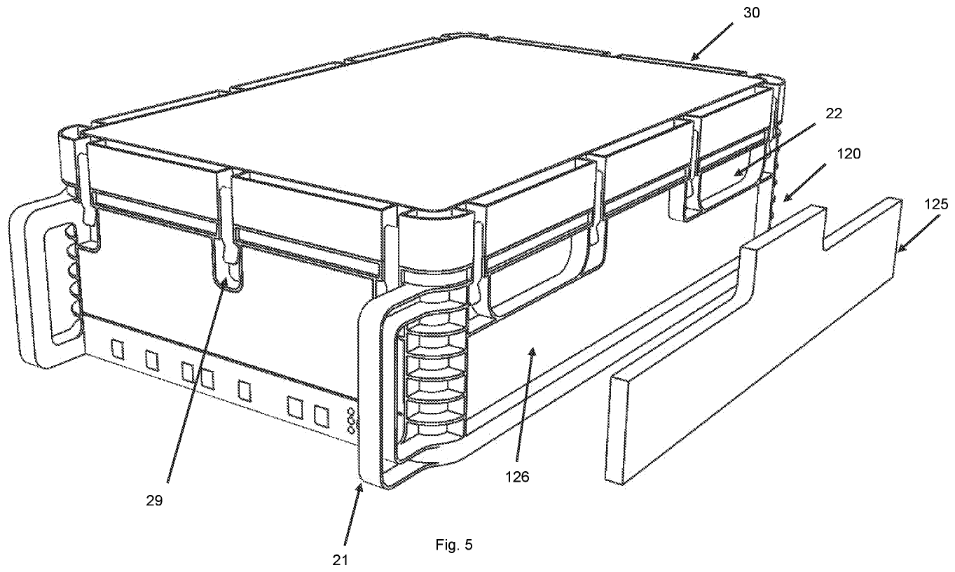

Referring now to FIG. 5, there is depicted a front perspective view of the embodiment of FIG. 1 in accordance with a third design. Where the features illustrated in a previous drawing are again shown, identical reference numerals have been used. In this structure, the housing for the base portion 120 is formed using a first layer of plastic 126 and a panel 125. The panel is advantageously rigid and may also made of plastic, but may be made of wood or another material. It is significantly thicker than the first layer of plastic 126 and therefore provides both resilience and insulative properties. The panel 126 is affixed to the first layer of plastic 126 by an adhesive. An inner surface of the panel 126 (with respect to the cooling module 10) may be covered in a reflective material, such as a metal foil and/or a separate support structure board. A reflective material may reflect radiant heat from escaping (similar to that found in house cavity walls and roof structures).

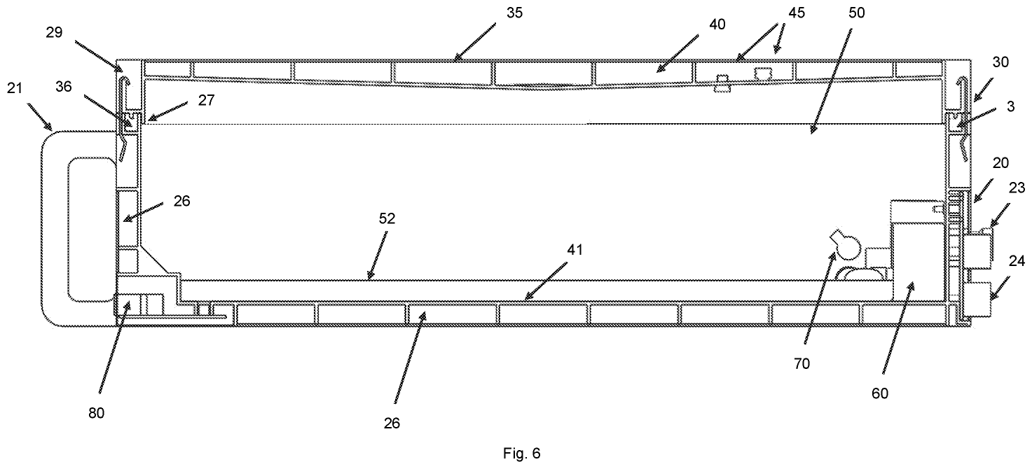

Other features of the cooling module 10 will now be described, irrespective of the structure of its housing. Referring now to FIG. 6, there is illustrated a cross-sectional view of the embodiment of FIG. 1. Where the features of previous drawings are shown, the same reference numerals have been used. In particular, a first layer of plastic 26 can be seen for the sidewalls of the base portion and the lower wall 41 of the base portion 20. Back removal handles 21, fluid connections 23 and power connector 24 are also visible. In addition, the internal volume 50 is shown. Within the internal volume 50, there is provided a heat exchanger 60 and a primary coolant manifold 70. Pressure release valve 45 is also shown.

The internal volume 50 defines a standardised envelope for a wide variety of Information Technology Equipment (ITE) types and configurations for the electronic component or device housed within the cooling module 10. This can be seen by the size and shape of the internal volume 50. The electronic device or devices can be generally planar (especially when mounted on a circuit board or otherwise elongate) and in that case, they may be mounted horizontally (with the plane of the device parallel to the lower wall and/or upper wall) or vertically (with the plane of the device perpendicular to the lower wall and/or upper wall). Devices may be stacked in either or both dimensions within the internal volume 50.

A number of further adaptations are shown, which individually and collectively increase the performance of the cooling module 10. The lid 30 is adapted, such that the internal surface of the upper wall 40 of the lid 30 slopes. As a result, the upper wall 40 is closer to the lower wall 41 in a central portion of the internal volume 50 and further away from the lower wall 41 at a peripheral portion of the internal volume 50. This allows improved pressure management and also provides a return path for condensation. Although this is shown for a specific (double-walled) structure of lid 30, it may be applied to an upper wall of the cooling module 10 with an alternative structure.

The base portion 20 is adapted to provide a seal when the lid 30 is coupled to the base portion 20. A deformable (preferably rubber) seal 28 is provided in the base portion. A projection 36 extends from the lid 30 and fits into the seal 28, to improve the quality of the seal between the base portion 20 and lid 30, by digging into the seal and preventing primary liquid coolant from emerging through the seal. Also shown is overhang 37 as part of the lid 30. This overhang 37 has a number of advantageous properties. Firstly, it improves the ability to locate the lid 30 correctly within the opening provided by the base portion 20. Secondly, it directs a condensation return path for the primary liquid coolant, when the lid 30 is placed on the base portion 20, and prevents this path from flowing directly to the seal 28. Thirdly, it causes the lid 30, when placed on a flat surface (such as a desk) away from the base portion 20, to extend further from the flat surface than would otherwise be the case. This allows the lid 30 to sit on a flat surface in a safe and controlled way. In this regard, the overhang 37 is advantageously longer than the projection 36.

A typical level of primary coolant 52 is shown for reference. Adaptations may be made to the lower wall 41, which may improve the flow of primary liquid coolant. For example, the lower wall 41 may be shaped in a similar way to the upper wall 40, with similar advantages (this may be advantageously implemented even if the upper wall 40 is not so-shaped). Additionally and alternatively, a coolant well (not shown) may be provided along the rim of the lower wall 41 to allow improved coolant collection and redirection towards the heat exchanger 60 (as will be discussed later).

The pressure release valve 45 is not intended or configured for normal pressure management, especially as this may result in loss of evaporated primary coolant. Rather, the pressure release valve 45 is configured to open only in the event of extreme pressures, for example a runaway event.

Also shown in FIG. 6 is an input/output (I/O) interface board 80, which allows connections between the electronic component or device (not shown) within the internal volume 50 and the connector and user interface panel 55. This I/O interface board 80 may be in accordance with that described in co-pending International Patent application number PCT/GB2017/053553, published as WO-2018/096360, entitled “I/O Circuit Board for Emersion-Cooled Electronics” and filed on 27 Nov. 2017, the contents of which are incorporated by reference in their entirety. Alternatives (for examples variations on the designs of board described in the co-pending International Patent application) are also possible.

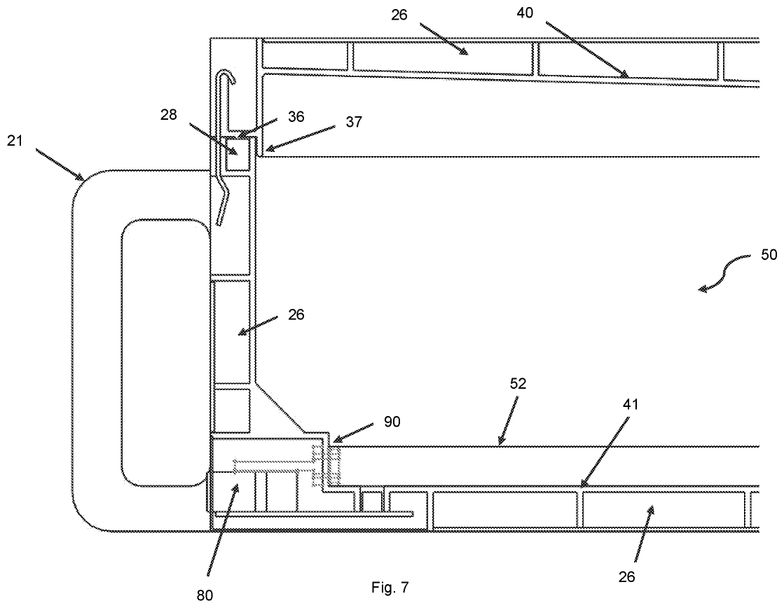

Referring next to FIG. 7, there is illustrated a portion of FIG. 6 in more detail. In addition to the features discussed above, FIG. 7 also shows a metal plate 90. Metal plate 90 allows the transfer of heat from electronics that form part of the cooling module 10, but are not located within the internal volume 50. These may include circuit boards forming part of the connector and user interface panel 55, for instance coupled by I/O interface board 80. The heat is transferred by the metal plate 90 to the primary liquid coolant, effectively from a ‘dry’ area of the cooling module (configured such that the primary liquid coolant cannot flow to this area or otherwise inaccessible by the primary liquid coolant). Thus, the metal plate 90 is advantageously positioned towards or adjacent to the lower wall 41 and preferably below the level 52 of the primary liquid coolant. This allows heat to transfer to the primary liquid coolant in most cases.

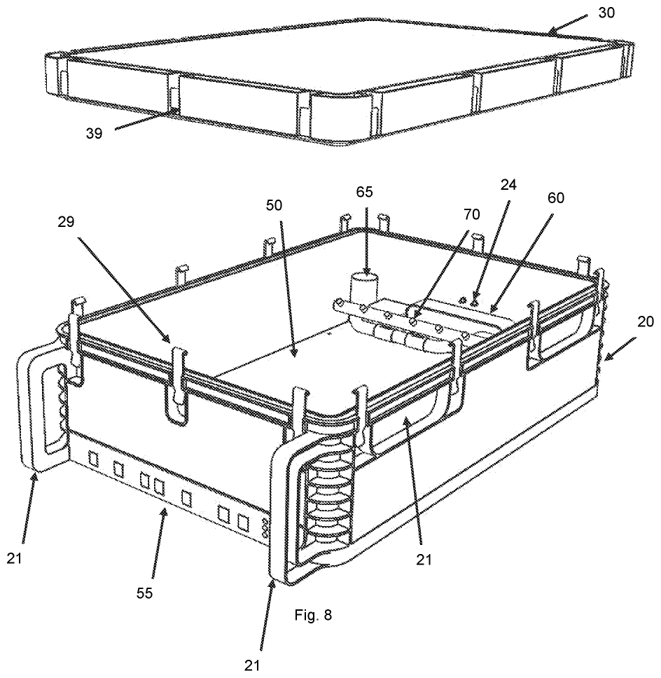

Referring next to FIG. 8, there is shown a front perspective view of the embodiment of FIG. 1 with a lid part 30 separated from a base portion 20. Many of the features shown have been depicted in earlier drawings and identical reference numerals have been used. In particular, the cooperating parts 39 on lid 30 for receiving the clips 29 are visible. The clips 29 and the cooperating parts 39 allow the lid 30 to be opened quickly (fast access) and without the need for a tool. Also, the internal portions of DC power connectors 24 are shown in this drawing.

The heat exchanger 60 and the primary coolant manifold 70 are also clearer in this drawing. The heat exchanger 60 is a plate heat exchanger and typically sized for 5 kW. The path of coolant is, for example, in accordance with that described in co-pending International Patent application number PCT/GB2017/053556, published as WO-2018/096362, entitled “Fluid Cooling System” and filed on 27 Nov. 2017, the contents of which are incorporated by reference in their entirety. In this approach, primary liquid coolant is received at the heat exchanger 60, where heat is transferred from the primary liquid coolant to the secondary liquid coolant. The primary liquid coolant is then provided to the manifold 70, from where the primary coolant is transferred to specific parts of the internal volume 50, based on the electronic device or devices provided therein. Heat sinks (not shown) may be provided on or around the electronic device or devices, especially in the form described in co-pending International Patent application number PCT/GB2018/052526 and published as WO-2019/048864, entitled “Heat Sink, Heat Sink Arrangement and Module for Liquid Emersion Cooling” and filed on 6 Sep. 2018, the contents of which are incorporated by reference in their entirety. Such heat sinks may assist the efficient transfer of heat from the electronic device or devices to the primary liquid coolant. The pump 65 causes the flow of primary liquid coolant. The primary liquid coolant is pumped from the internal volume 50 to the heat exchanger 60 and then follows the path as described above. In this regard, a coolant well (as described above) may allow efficient flow of the primary liquid coolant, effectively by defining a reservoir for the primary liquid coolant for pumping. A second pump (not shown) may also be provided in the internal volume, in particular for redundancy. In other words, even in the failure of one of the pumps provided, second pump will allow the flow of primary liquid coolant to continue, even to the extent required to allow efficient cooling (fail over functionality). The second pump may also be configured to operate in parallel with the first pump 65, in some embodiments or cases.

A plastic housing is preferred (in the embodiment discussed above) and as noted above, the housing may be made only partially of plastic in some embodiments. In other embodiments, the housing need not include plastic. Options for materials that may be used together with or as an alternative to plastic may include a metal such as cast steel, sheet metal or aluminium. Where a metal or other generally thermally conductive material is used, an insulation (for example, using a foam material) may be provided externally around the housing to prevent heat loss. Some features described herein, such as ribs for structure and a double-wall arrangement may be used as a result of material choice, such as the use of plastic as a construction material, so may not be needed in a housing formed from or comprising metal with external insulation panels.

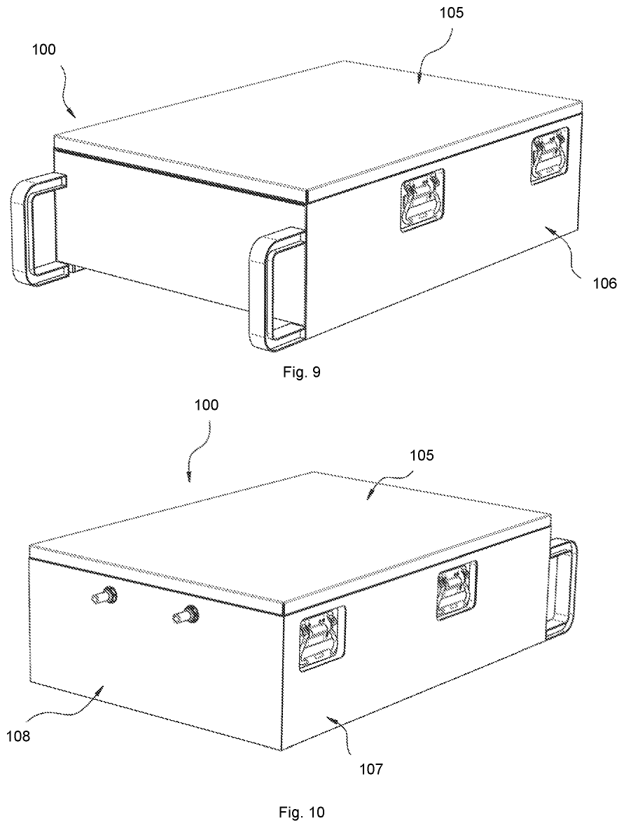

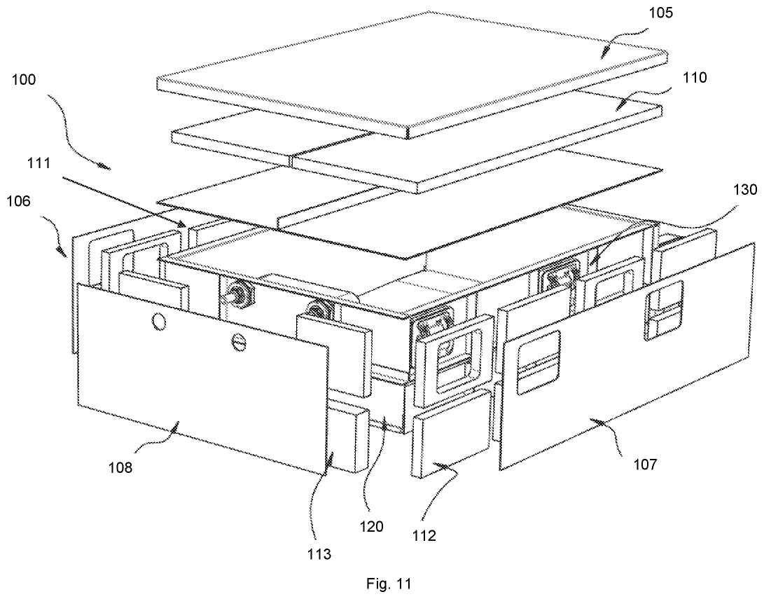

A further embodiment will now be discussed with reference to FIG. 9, in which there is shown a front perspective view of a second embodiment of a cooling module 100. Reference is also made to FIG. 10, in which there is shown a rear perspective view of the embodiment of FIG. 9. The cooling module 100 has: a top outer surface 105; a first side outer surface 106; a second side outer surface 107; and a back outer surface 108, each of which is a fascia plate. The fascia plates can moulded, fabricated from plastic or fabricated from sheet metal (for instance, steel or aluminium).

Significantly (and unlike the embodiment discussed previously), the main parts of the cooling module 100 use a sheet metal fabrication, for example steel or aluminium. This will be discussed by referring to FIG. 11, in which there is depicted an exploded rear perspective view of the embodiment of FIGS. 9 and 10. In this drawing, additional inner features of the cooling module 100 can be seen. In particular, the cooling module 100 comprises: top insulation 110; first side insulation 111; second side insulation 112; back insulation 113; inner box structure 120; and ribbing 130.

The inner box structure 120 holds the IT being cooled and is fabricated using a sheet metal construction, as discussed above. The inner box structure 120 has external ribbing 130 (which may be omitted in variants). This ribbing 130 not only provides additional structural integrity and rigidity, but also holds in place insulation 110, 111, 112, 113 that cases the entire inner box 120. The purpose of the insulation 110, 111, 112, 113 is to retain as much heat as possible inside the inner box 120, as opposed to transferring it into the surrounding air. This is similar to the approach taken in the previously-described embodiments. The outer surface fascia plates 105, 106, 107, 108 sandwich the insulation 110, 111, 112, 113 in place, protect the insulation 110, 111, 112, 113 from any damage (for example, when the chassis is regularly pulled in and out of a rack) and provides an aesthetic ‘cover’. The insulation 110, 111, 112, 113 may be held in place by the ribbing 130 alone, by the sandwiching between the inner box 120 and outer surface fascia plates 105, 106, 107, 108 and/or by other methods such as adhesive or fixings.

Other details of the second embodiment of the cooling module 100 may be the same as the first embodiment of the cooling module 1, as discussed above. Alternatively, these may be varied.

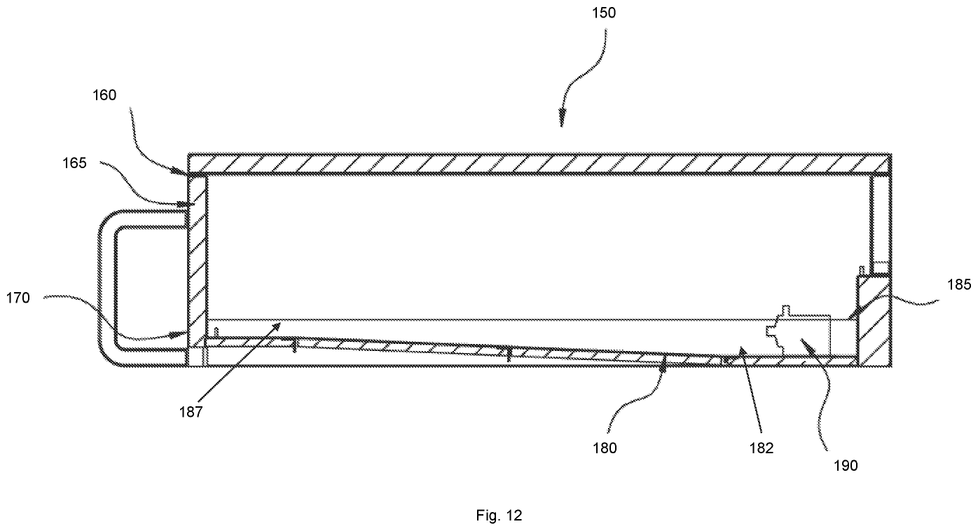

A further aspect of a cooling module according to the disclosure (in respect of any embodiment as herein discussed) will now be detailed. To that end, referring now to FIG. 12, there is illustrated a schematic cross-sectional view in accordance with another embodiment of the disclosure. A cooling module 150 comprises: inner walls 160 (for example having an inner box structure, as discussed above); outer walls 170; insulation 165 between the inner walls 160 and outer walls 170; an angled base structure 180, defining a sump 182; and a pump 190. The details of the inner walls 160, outer walls 170 and the insulation 165 may be similar to (or the same as) any other embodiment described herein (including sheet metal, moulded plastic or die cast versions of a cooling module).

The inner walls 160 of the cooling module define the angled base 180, which creates the sump 182 (for example, in the form of a gutter) at the back of the cooling module 150 (or front, in other words an elongated end of the cooling module 150). The pump 190 (or pumps) are mounted in the sump 182. This allows the pump or pumps 190 to have a high coolant level 185 therearound. This may assist in priming of the pump or pumps 190, without the need to have a high coolant level throughout the cooling module 150. In other words, the level of coolant 187 away from the sump 182 may be low. This reduces the amount of coolant that needs to be used compared with the use of a non-angled base.

In general terms, there may be considered a cooling module for containing a heat-generating electronic device within an internal volume, together with a liquid coolant. The cooling module comprises a housing defining an upper wall, a lower wall opposite the upper wall and at least one sidewall connecting the lower wall and upper wall. The upper wall, lower wall and at least one sidewall define the internal volume. Essentially, this may define a container for an electronic device (or devices) and sealable to include a liquid coolant. In the preferred embodiment, the at least one sidewall comprises four sidewalls, for instance such that the housing has a generally cuboid shape. In an embodiment, the housing comprises: a base portion, defining the lower wall and a first part of the at least one sidewall; and a lid, separable from the base portion and defining the upper wall and a second part of the at least one sidewall. Beneficially, the base portion and lid are arranged for cooperation (by mating or association, for instance) so as to form the internal volume. In other words, the container may have a lid that separates from the base, but when the base and lid are put together, the internal volume may be sealed. In embodiments, the heat-generating electronic device comprises ITE, for example one or more of: a computer processing unit; a graphical processing unit; a network switch; a computer storage device; one or more disk drives; and a power supply unit.

In some embodiments, the housing is (substantially) made of plastic. Plastic may beneficially provide ease of manufacture, whilst allowing insulative properties. Additionally or alternatively, the housing may be made of metal, for instance sheet metal or cast metal. Suitable metals may include steel and/or aluminium.

Optionally, the cooling module may comprise the heat-generating electronic device and/or the liquid coolant within the internal volume. According to some aspects of the disclosure, the lid optionally comprises a projection and the base portion comprises a sealing part that is configured to receive the projection of the lid when the base part and lid cooperate so as to create a seal when the internal volume is formed. In such a case, the sealing part is preferably compressible by the projection of the lid. Alternatively, the sealing part comprises a recess arranged to receive the projection of the lid when the base part and lid cooperate.

The disclosure provides a number of advantageous features (approaches) are considered in connection with the housing. In accordance with the disclosure any one or more of these may be provided (in any combination, some combinations also providing synergistic advantages). These advantageous features may improve resilience, robustness, flexibility (in terms of allowing a greater range of electronic devices to be housed in the internal volume) and/or thermal efficiency.

In a first approach (a), the at least one sidewall comprises: a first layer of plastic; and a reinforcement adaptation (which may be made of plastic) that improves a resilience of the first layer of plastic to pressure from the internal volume and/or a thermal insulation ability of the first layer of plastic (compared with the first layer of plastic alone). This may improve resilience, flexibility and thermal efficiency, in particular. For example, the reinforcement adaptation may comprise one or more of: (i) a second layer of plastic, spaced from the first layer of plastic so as to form a double-walled housing; (ii) a support structure attached to or formed integrally with the first layer of plastic, formed perpendicular to the first layer of plastic and coupled to one or more of the lower wall, the upper wall and the at least one sidewall of the housing, so as to provide reinforcement (for example, forming ribs, pins and/or fins), with the support structure optionally being formed to have a pattern comprising one or more of: elongated ribs; a criss-cross; and a tessellated shape; and (iii) a panel attached to the first layer of plastic (and which may be thicker than the first layer) and coupled to the lower wall and/or upper wall of the housing, so as to provide reinforcement. The panel may have a reflective inner surface.

In a second approach (b), the lower wall and/or the upper wall have a central portion that is closer to the opposite wall than at least one peripheral portion or that is defines a surface of the internal volume that is closer to an outer surface of the lower wall in an outer portion or edge portion of the internal volume (that is, a periphery) than in another portion (for example, an inner or central portion or another edge portion) of the internal volume. In one respect, this may improve flexibility and thermal efficiency, in particular. In other respects, it may allow different heights of liquid coolant to settle within the internal volume, for instance defining a sump or gutter. In embodiments, the upper wall and/or lower wall is sloped between the central portion and at least one edge adjacent the at least one sidewall. Additionally or alternatively, the peripheral portion may be defined by a gutter formed along at least one edge adjacent the at least one sidewall. In such a case, the gutter may be spaced further apart from the opposite wall than the central portion. The internal volume may have an elongated shape and the upper and/or lower wall may sloped at an elongated end of the internal volume, for instance. One or more pumps may be positioned on the surface of the internal volume that closer to an outer surface of the lower wall (for example, in the sump, gutter or thinner portion of the lower wall. In particular, this may assist in priming of the pump or pumps, without the need to have a high coolant level throughout the internal volume. The lower wall may not be a single part and may comprise: a first wall defining the inner surface; and a second wall (separated from the first wall) defining the outer surface.

In a third approach (c), the second part of the at least one sidewall of the lid comprises a ridge arranged to overlap the first part of the at least one sidewall of the base portion proximate the internal volume during the cooperation of the base portion and the lid. This may improve robustness, resilience, flexibility and thermal efficiency. In such a case, the ridge of the lid is advantageously longer than the projection of the lid. This may allow the ridge of the lid to project the lid from a surface.

In a fourth approach (d), the cooling module further comprises a thermally conductive component arranged to have a first portion located within the internal volume and to pass through the at least one sidewall so as to have a second portion outside the internal volume and thereby allow conduction of heat from outside the internal volume to within the internal volume. This may improve resilience, flexibility and thermal efficiency, in particular. Preferably, the thermally conductive component is made of metal (such as aluminium). In some embodiments, the thermally conductive component is sized to carry at least 10 W of thermal power.

A number of optional features and/or implementation details will now be discussed in accordance with any aspect or approach provided herein. For example, the cooling module advantageously further comprises a heat exchanger, configured to receive liquid coolant from the internal volume (which may be considered a primary coolant) and transfer heat from the liquid coolant to a heat sink coolant (which may be considered a secondary coolant). Preferably, the heat exchanger is within the internal volume. This may allow more efficient cooling. Advantageously, the heat exchanger is configured to avoid substantial phase change of the liquid coolant within the internal volume (although some evaporation is possible even without substantial phase change). In some embodiments, the heat sink coolant is a second liquid coolant received from external the cooling module, for example water (which may be provided from a building main water supply). Then, the cooling module beneficially further comprises: a coolant inlet, for receiving (or configured to receive) the second liquid coolant and providing the received second liquid coolant to the heat exchanger; and a coolant outlet, for receiving (or configured to receive) the second liquid coolant from the heat exchanger, following heat transfer. Preferably, the cooling module further comprises a pump, configured to cause liquid coolant to flow between the heat exchanger and the (remainder of the) internal volume. Advantageously, the pump is located or provided in the internal volume.

The heat-generating electronic device may comprise a planar circuit board (for example in the case of a CPU, GPU or network switch). In some embodiments, the planar circuit board is mounted in the internal volume such that the plane of the circuit board extends substantially parallel to the at least one sidewall. For example, the plane of the circuit board may extend substantially perpendicular to the upper wall or lower wall. Alternatively, the planar circuit board is mounted in the internal volume such that the plane of the circuit board extends substantially parallel to the upper wall or lower wall (for example, substantially perpendicular to the at least one sidewall). Both options are possible when the cooling module comprises multiple planar circuit boards, at least of which may be oriented in one way and at least another of which may be oriented in another way.

Preferably, the quantity of liquid coolant within the internal volume is insufficient to cover the heat-generating electronic device (so that the heat-generating electronic device is not fully submerged). In embodiments, at least 20%, 25%, 50% or 75% of a surface area of the heat-generating electronic device is not covered by the liquid coolant. The level of liquid coolant in the cooling module (when oriented horizontally) may be no more than 20%, 15%, 10% or 5% of the height of the cooling module.

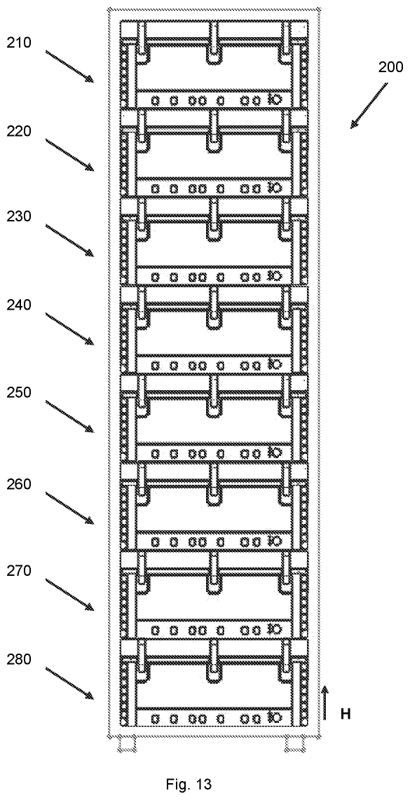

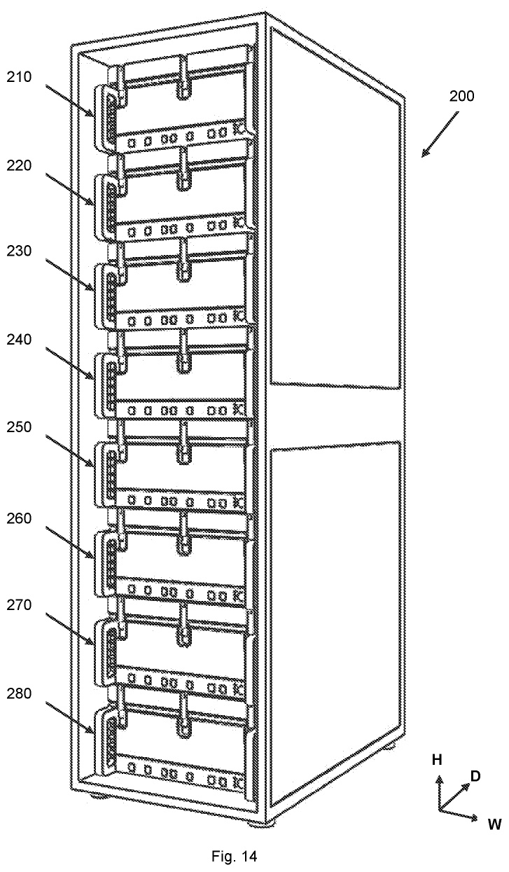

The focus of the preceding description has been on the cooling module 10. Such a cooling module beneficially allows a wide variety of ITE to be housed within. Locating different types of ITE in cooling modules may be advantageous for server configurations, which are typically mounted in racks. Aspects of the disclosure concerning the provision of cooling modules within a server rack will now be discussed. Reference is made to FIG. 13, which depicts a front face view of a server rack populated with cooling modules. The server rack 200 is populated with 8 cooling modules: a first cooling module 210; a second module 220; a third cooling module 230; a fourth cooling module 240; a fifth cooling module 250; a sixth cooling module 260; a seventh cooling module 270; and an eighth cooling module 280.

The size of each (every) cooling module in the height dimension of the server rack 200 (H) is identical (although an alternative in which the size of each or every cooling module in the height dimension may be selected from only one of two options). The other outer dimensions of all of the cooling modules are also the same. In fact, each of the cooling modules is in accordance with the embodiment of FIGS. 1 to 8, although this is not strictly necessary. However, the cooling modules do not all have the same type of ITE housed within them. In this embodiment, the first cooling module 210 comprises a network switch, the second cooling module 220 comprises a Graphical Processing Unit (GPU), the third cooling module 230 comprises Power Supply Units (PSUs), the fourth cooling module 240 comprises disk drives (a collection of disk drives that have not been configured to act as a redundant array of independent disk drives, also termed JBOD), the fifth cooling module 250 comprises motherboards, referenced as a Central Processing Unit (CPU), the sixth cooling module 260 comprises PSUs, the seventh cooling module 270 comprises a CPU and the eighth cooling module 280 comprises a CPU.

This is simply an example and other configurations are possible. Nevertheless, a number of principles can be understood. Firstly, two computational units are provided in adjacent cooling modules (CPU, GPU, network switch, disk drive) and then one power unit (PSU). Also, the power requirement of each computational unit is preferably the same (in this case approximately 4 kW). The cooling modules providing power (in this case, the third cooling module 230 and sixth cooling module 260) are configured to provide the same amount of power, in this case 25 kW. Each of these cooling modules comprises redundant power supplies (N+1). Specifically, six PSU devices are provided in each cooling module, each PSU providing 5 kW of electrical power. However, the cooling module is only intended to provide 25 kW of electrical power. Moreover, it will be noted that the total power requirement of each of the computing modules (first cooling module 210, second cooling module 220, fourth cooling module 240, fifth cooling module 250, seventh cooling module 270 and eighth cooling module 280) is 24 kW. Thus, only one power cooling module should be needed to supply all of the power required for all of the computing cooling modules. However, two power cooling modules are provided, again for redundancy purposes.

With reference to FIG. 14, there is depicted a front perspective view of the embodiment of FIG. 13. In this drawing, the height dimension (H), width dimension (VV) and depth dimension (D) are shown. In this form, the server rack 200 is able to provide a standardised platform for liquid cooling modules. Standardised power and secondary coolant connectors can be provided to each module, in particular, to match the coolant connectors 23 and power connectors 24 (as shown in FIGS. 1 to 8).

The server rack 200 structure scales on a modular basis and not on a rack basis. This allows improvements in rack efficiency and reductions in cost.

Benefits of the aspects of the present disclosure may include: improved thermal efficiency (which may allow the temperature of the secondary liquid coolant to be higher than would otherwise be possible); improved quality and reliability; reduced cost; make the cooling module 10 easier to transport without the primary liquid coolant, which can still be added before operation; lower heat loss to the environment; improved ability to service and/or repair; better ability to manufacture at scale.

In general terms and according to another aspect of the disclosure, there may be provided a computing system, comprising: a server rack for holding a plurality of computing units at different levels in a height dimension; a first cooling module for mounting in the server rack, comprising a first housing enclosing a first computing unit, the first housing having a first size in the height dimension; and a second cooling module for mounting in the server rack, comprising a second housing enclosing a second computing unit that is a different type of information technology equipment than that of the first computing unit, the second housing having a second size in the height dimension. Advantageously, the first and second sizes are the same. Housing different types of ITE within different cooling modules of the same front profile within a server rack marks a significant departure from existing server racks for cooling modules. Such an approach allows improves flexibility, scalability and thermal efficiency.

In another sense, there may be considered a computing system, comprising: a server rack for holding a plurality of computing units; a first cooling module as herein disclosed for mounting in the server rack, comprising a first heat-generating electronic device as a first computing unit; and a second cooling module as herein disclosed for mounting in the server rack, comprising a second heat-generating electronic device as a second computing unit. Beneficially, a height of the housing of the first cooling module is the same as a height of the housing of the second cooling module. Advantageously, the first computing unit and the second computing unit are different types of information technology equipment. It may be especially beneficial for the cooling modules to be in accordance with any of those described in the present disclosure (although this does not mean that they necessary have all of the features of any particular embodiment of a cooling module).

In yet a further sense, there may be considered a computing system, comprising: a server rack for holding a plurality of computing units at different levels in a height dimension; and a plurality of cooling modules, each cooling module housing a respective one of the computing units. All of the cooling modules either have the same size in the height dimension or one of two different sizes in the height dimension. The computing units include at least two different types of ITE (and preferably at least three different types of ITE, if two different sizes are used). In other words, different types of ITE may be housed in cooling modules of the same height or of only two different heights (an extension embodiment, may consider different types of ITE being housed in cooling modules of only three different heights, but this is less preferred). In particular embodiments, the other (at least outer) dimensions of the cooling modules are the same for all cooling modules.

There are preferably more than two cooling modules. In that case, it may be considered that each of the computing units held in the server rack is housed in a respective cooling module. Then, each of the cooling modules advantageously has the same size in the height dimension. In other words, the server rack holds different types of ITE in modules that all have the same height. In the preferred embodiment, the size of the first and second housings in all (outer and/or inner) dimensions are the same. This may be applied to all cooling modules held in the server rack. The server rack may be configured to hold at least 4, 6 or 8 computing units. At least one of the first computing unit and the second computing unit (preferably both and more preferably all cooling modules in the server rack) may be configured to consume (that is, rated for) 4 kW of electrical power.

Advantageously, each of the first and second computing units (and preferably all of the plurality of computing units each) comprise: at least one computer processing unit (CPU); at least one graphical processing unit (GPU); at least one power supply unit (PSU); one or more networking switches; and one or more disk drives. In some embodiments, the first computing unit is made up of multiple devices of the same type of information technology equipment and/or the second computing unit is made up of multiple devices of the same type of information technology equipment. Optionally, any one of the cooling modules held in the server rack may be made up of multiple devices of the same type of information technology equipment.

In some embodiments, the first cooling module and second cooling module are mounted adjacently in the server rack. Then, the first computing unit may comprise one or more power supply units and the second computing unit comprise a different type of information technology equipment than that of the first computing unit (or vice versa). In that case, the computing system may further comprise: a third cooling module mounted in the server rack adjacent to the first cooling module on an opposite side to the second cooling module. The third cooling module beneficially comprises a third housing enclosing a third computing unit that is a different type of information technology equipment than that of the first computing unit. Preferably, the third housing has a third size in the height dimension that is the same as the first and second sizes.

In some embodiments, the first computing unit comprises at least one power supply unit (PSU). Then, one or more of a number of optional features may be provided. For example, the at least one PSU of the first computing unit may be configured to provide sufficient power to supply the respective computing units housed in each of at least 6 other cooling modules. In another case, the at least one PSU of the first computing unit is configured to provide at least 25 kW of power. Additionally or alternatively, the at least one PSU of the first computing unit comprises a plurality of PSUs. Optionally in that case, each PSU is preferably configured to provide sufficient power to supply all of the computing units in a single, other cooling module. In another option where the at least one PSU of the first computing unit comprises a plurality of PSUs, the number of PSUs in the plurality of PSUs may be configured to provide redundancy. Preferably all such options apply. In an embodiments, each of at least two of the cooling modules (where there are at least 3 or 4 cooling modules held in the server rack) comprises a respective power supply unit (PSU).

The cooling modules may be in accordance with any aspect of the present disclosure. For example, the first cooling module may further house a first cooling liquid sealed with the first computing unit in a first internal volume and/or the second cooling module further houses a second cooling liquid sealed with the second computing unit in a second internal volume. Optionally, the first cooling module further comprises a first heat exchanger (which may be within the first housing), configured to receive the first cooling liquid from the first internal volume and transfer heat from the first liquid coolant to a first heat sink coolant and/or the second cooling module further comprises a second heat exchanger (which may be within the second housing), configured to receive the second cooling liquid from the second internal volume and transfer heat from the second liquid coolant to a second heat sink coolant.

In the preferred embodiment, the first and second heat sink coolants are both a secondary coolant liquid received from external the first and second cooling modules through respective coolant inlets. Then, the server rack preferably further comprises piping for providing the secondary coolant liquid to the respective coolant inlets of each of the first and second cooling modules.

Optionally, the first cooling module further comprises a first pump, configured to cause the first liquid coolant to flow between the first internal volume and the first heat exchanger and/or the second cooling module further comprises a second pump, configured to cause the second liquid coolant to flow between the second internal volume and the second heat exchanger heat exchanger.

Although specific embodiments have now been described, the skilled person will appreciate that various modifications and alternations are possible. With reference to the cooling module 10, a wide variety of different structures may be possible. For example, the housing may comprise a single layer of plastic with any adaptation to provide reinforcement and/or insulation to the cooling module. Where a support structure is provided (as shown in FIGS. 3 and 4, alternatives to ribs are possible, such as pin-based or fin-based structures. Also, the shape of the support structure need not be based on tessellated hexagons. For instance, vertical lines, horizontal lines, criss-crossing lines or other shapes may be provided. Combinations of different shapes may also be possible.

Two stages of liquid cooling (the primary liquid coolant and the secondary liquid coolant) have been described. However, other cooling stages may be provided, which may involve liquid cooling (that is, one or more further liquid coolants). Redundancy may be provided at any stage, in terms of heat exchangers, coolant manifolds or piping.

Although it is believed that all types of ITE have been mentioned in the disclosure, the skilled person will recognise that other types of ITE are covered by the disclosure, even if not explicitly identified.

All of the features disclosed herein may be combined in any combination, except combinations where at least some of such features and/or steps are mutually exclusive. In particular, the preferred features of each aspect of the disclosure are generally applicable to all aspects of the disclosure and the features of all of the aspects may be used in any combination. Likewise, features described in non-essential combinations may be used separately (not in combination).

A method of manufacturing and/or operating any of the devices disclosed herein is also provided. The method may comprise steps of providing each of features disclosed and/or configuring the respective feature for its stated function.

1. A computing system, comprising:
a server rack configured to hold a plurality of computing units at different levels in a height dimension;
a first cooling module configured to be mounted in the server rack, comprising a first housing enclosing a first computing unit, the first housing having a first size in the height dimension; and
a second cooling module configured to be mounted in the server rack, comprising a second housing enclosing a second computing unit that is a different type of information technology equipment than that of the first computing unit, the second housing having a second size in the height dimension; and
wherein the first and second sizes are the same.

2. The computing system of claim 1, wherein the size of the first and second housings in all dimensions are the same.

3. The computing system of claim 1, wherein each of the computing units held in the server rack is housed in a respective cooling module, each of the cooling modules having the same size in the height dimension or one of two different sizes in the height dimension.

4. The computing system of claim 1, wherein the each of the first and second computing units comprise at least one selected from the group consisting of: at least one computer processing unit (CPU); at least one graphical processing unit (GPU); at least one power supply unit (PSU); one or more networking switches; and one or more disk drives.

5. The computing system of claim 1, wherein the first computing unit is made up of multiple devices of the same type of information technology equipment and/or the second computing unit is made up of multiple devices of the same type of information technology equipment.

6. The computing system of claim 1, wherein the first cooling module and second cooling module are mounted adjacently in the server rack, the first computing unit comprising one or more power supply units and the second computing unit comprising a different type of information technology equipment than that of the first computing unit.

7. The computing system of claim 6, further comprising:
a third cooling module mounted in the server rack adjacent to the first cooling module on an opposite side to the second cooling module, the third cooling module comprising a third housing enclosing a third computing unit that is a different type of information technology equipment than that of the first computing unit.

8. The computing system of claim 7, wherein the third housing has a third size in the height dimension that is the same as the first and second sizes.

9. The computing system of claim 1, wherein the server rack is configured to hold at least 4 computing units, each computing unit being housed in a respective cooling module, each of the cooling modules having the same size in the height dimension.

10. The computing system of claim 9, wherein the first computing unit comprises at least one power supply unit (PSU) and wherein at least one of:
the at least one PSU of the first computing unit is configured to provide sufficient power to supply the respective computing units housed in each of at least 6 other cooling modules;
the at least one PSU of the first computing unit is configured to provide at least 25 kW of power;
the at least one PSU of the first computing unit comprises a plurality of PSUs, each PSU being configured to provide sufficient power to supply all of the computing units in a single, other cooling module; and
the at least one PSU of the first computing unit comprises a plurality of PSUs, the number of PSUs in the plurality of PSUs being configured to provide redundancy.

11. The computing system of claim 9, wherein at least two of the cooling modules each comprise a respective power supply unit (PSU).

12. The computing system of claim 1, wherein the first cooling module further houses a first cooling liquid sealed with the first computing unit in a first internal volume and the second cooling module further houses a second cooling liquid sealed with the second computing unit in a second internal volume.

13. The computing system of claim 12, wherein the first cooling module further comprises a first heat exchanger, configured to receive the first cooling liquid from the first internal volume and transfer heat from the first liquid coolant to a first heat sink coolant and wherein the second cooling module further comprises a second heat exchanger, configured to receive the second cooling liquid from the second internal volume and transfer heat from the second liquid coolant to a second heat sink coolant.

14. The computing module of claim 13, wherein the first heat exchanger is within the first housing and the second heat exchanger is within the second housing.

15. The computing module of claim 13, wherein the first and second heat sink coolants are both a secondary coolant liquid received from external the first and second cooling modules through respective coolant inlets, the server rack further comprising piping for providing the secondary coolant liquid to the respective coolant inlets of each of the first and second cooling modules.

16. The cooling module of claim 13, wherein the first cooling module further comprises a first pump, configured to cause the first liquid coolant to flow between the first internal volume and the first heat exchanger and wherein the second cooling module further comprises a second pump, configured to cause the second liquid coolant to flow between the second internal volume and the second heat exchanger heat exchanger.

17. The computing system of claim 1, wherein at least one of the first computing unit and the second computing unit is configured to consume 4 kW of electrical power.

18. A cooling module, for containing a heat-generating electronic device within an internal volume, together with a liquid coolant, the cooling module comprising a housing defining an upper wall, a lower wall opposite the upper wall and at least one sidewall connecting the lower wall and upper wall, the upper wall, lower wall and at least one sidewall defining the internal volume; and
wherein one or more of:
(a) the at least one sidewall comprises a first layer of material and a reinforcement adaptation that improves a resilience of the first layer of material to pressure from the internal volume and/or a thermal insulation ability of the first layer of material;
(b) the lower wall and/or the upper wall have a central portion that is closer to the opposite wall than at least one peripheral portion or the lower wall defines a surface of the internal volume that is closer to an outer surface of the lower wall in an edge portion of the internal volume than in another portion of the internal volume;
(c) the housing comprises: a base portion, defining the lower wall and a first part of the at least one sidewall; and a lid, separable from the base portion and defining the upper wall and a second part of the at least one sidewall, the base portion and lid being arranged for cooperation so as to form the internal volume and the second part of the at least one sidewall of the lid comprising a ridge arranged to overlap the first part of the at least one sidewall of the base portion proximate the internal volume during the cooperation;
(d) the cooling module further comprises a thermally conductive component arranged to have a first portion located within the internal volume and to pass through the at least one sidewall so as to have a second portion outside the internal volume and thereby allow conduction of heat from outside the internal volume to within the internal volume.

19. (canceled)

20. The cooling module of claim 18, wherein the at least one sidewall comprises four sidewalls, such that the housing has a generally cuboid shape.

21.-40. (canceled)

41. A computing system, comprising:
a server rack for holding a plurality of computing units;
a first cooling module for mounting in the server rack, comprising a first heat-generating electronic device as a first computing unit, the first cooling module being in accordance with claim 18; and
a second cooling module for mounting in the server rack, comprising a second heat-generating electronic device as a second computing unit, the second cooling module being in accordance with claim 18; and
wherein a height of the housing of the first cooling module is the same as a height of the housing of the second cooling module.

42. (canceled)
